(19) United States
(12) Patent Application Publication
(10) Pub. No.: US 2012/0037202 A1
(43) Pub. Date: Feb. 16, 2012

(54) CORD PLATE FOR PHOTOVOLTAIC MODULE

(76) Inventor: Justin C. Gosnell, Perrysburg, OH (US)

(21) Appl. No.: 13/208,867

(22) Filed: Aug. 12, 2011

Related U.S. Application Data
(60) Provisional application No. 61/373,703, filed on Aug. 13, 2010.

(51) Int. Cl. H01L 31/042; H02G 3/18; H01L 31/18

(52) U.S. Cl. 136/244; 29/890.033; 174/650

(57) ABSTRACT

A cord plate for a photovoltaic module is configured to receive one or more flowable sealants.

### CROSS-REFERENCE TO RELATED APPLICATIONS

This application claims the benefit of U.S. Provisional Patent Application No. 61/373,703, filed Aug. 13, 2010, which is incorporated herein by reference in its entirety.

### FIELD OF THE INVENTION

Embodiments of the present invention generally relate to cord plates for photovoltaic modules and methods for manufacturing photovoltaic modules.

### BACKGROUND OF THE INVENTION

A cord plate attaches to a photovoltaic module and permits the module to be electrically connected to other modules in a photovoltaic array. The cord plate serves as a junction box and includes access holes for electrical connections. If these access holes are not adequately sealed, moisture may enter the module's electrical connections and reduce performance or cause failure.

### BRIEF DESCRIPTION OF THE DRAWINGS

FIG. 1 is a bottom perspective view of a photovoltaic module.

FIG. 2 is an exploded view of a photovoltaic module.

FIG. 3 is a top perspective view of a cord plate.

FIG. 4 is a bottom perspective view of a cord plate.

FIG. 5A is a perspective view of a cap for an inner cavity of a cord plate.

FIG. 5B is a perspective view of a cap for an inner cavity of a cord plate.

FIG. 6 is a perspective view of a cord plate and an adhesive layer.

FIG. 7 is a cross sectional side view of a cord plate filling with sealant.

FIG. 8 is a cross sectional side view of a cord plate filling with sealant.

FIG. 9 is a cross sectional side view of a cord plate filling with sealant.

FIG. 10 is a cross sectional side view of a cord plate filling with sealant.

FIG. 11 is a cross sectional side view of a cord plate filling with sealant.

FIG. 12 is a flow chart of a method for filling a cord plate with sealant.

FIG. 13 is a flow chart of a method for filling a cord plate with sealant.

FIG. 14 is a perspective view of a cap for an inner cavity of a cord plate.

FIG. 15 is a cross sectional side view of a cord plate filling with sealant.

FIG. 16 is a cross sectional side view of a cord plate filling with sealant.

FIG. 17 is a cross sectional side view of a cord plate filling with sealant.

FIG. 18 is a cross sectional side view of a cord plate filling with sealant.

FIG. 19 is a flow chart of a method for filling a cord plate with a first sealant and a second sealant.

### DETAILED DESCRIPTION OF THE INVENTION

The problem of moisture entering a photovoltaic module through the cord plate is solved by creating an improved cord plate with an electrical connection compartment configured to receive a flowable sealant. Manufacturing a waterproof cord plate is critical to producing a saleable module. For example, to achieve Underwriters Laboratories' (UL) certification, the module must pass a wet high potential (hipot) test where the module is submerged in water. The module must also pass a wet test where a jet of water is sprayed at the electrical connections and outer surfaces. Since the junction box houses several electrical connections, the junction box is often targeted by the water jet. To ensure passage of these certification tests, an improved cord plate has been invented and is described herein.

In one aspect, a cord plate for a photovoltaic module may include a bottom surface and an inner cavity. The inner cavity may include a first partition separating a first chamber from a second chamber, a second partition separating the second chamber from a third chamber, a first passage extending from the first chamber to the bottom surface, a second passage extending from the second chamber to the bottom surface, and a third passage extending from the third chamber to the bottom surface. The cord plate may also include first conductor housing connected to the first chamber and a second conductor housing connected to the second chamber. The first conductor housing may include a first filling hole. Similarly, the second conductor housing may include a second filling hole. The inner cavity may include a first access hole extending from the first chamber to the bottom surface and a second access hole extending from the third chamber to the bottom surface. The cord plate may further include a cap configured to attach atop the inner cavity, and the cap may have a vent hole. The cap may also include a first weep hole and a second weep hole.

In another aspect, a method for manufacturing a photovoltaic module may include providing a photovoltaic module including a cover plate and positioning a bottom surface of a cord plate proximate to a hole in the cover plate. The cord plate may include an inner cavity extending to the bottom surface. The method may include filling the inner cavity with a flowable sealant wherein the sealant flows from the inner cavity to the hole in the cover plate. The method may also include applying an adhesive layer between the cover plate and the cord plate, wherein the adhesive layer comprises an opening aligned with the hole in the cover plate. In addition, the method may include inserting a first conductor into the inner cavity through a first opening in the cord plate. Similarly, the method may include inserting a second conductor into the inner cavity through a second opening in the cord plate. The inner cavity may include a first filling hole. Similarly, the inner cavity may include a second filling hole. The inner cavity may include a vent hole. The inner cavity may include a plurality of chambers interconnected to form a filling pathway extending from the first filling hole to the vent hole. In particular, the inner cavity may include a first partition separating a first chamber from a second chamber, a second partition separating the second chamber from a third chamber, a first passage extending from the first chamber to the bottom surface, a second passage extending from the second chamber to the bottom surface, and a third passage extending from the third chamber to the bottom surface. The inner cavity may include a cap having a vent hole extending from the second chamber to an external surface of the cap. The cord plate may include a first conductor housing connected to the first chamber. The first conductor housing may include a first filling hole. The method may include injecting a first flowable sealant into the first filling hole. The first flowable sealant may flow from an inner surface of the first conductor housing into the first chamber. The first flowable sealant may flow from the first chamber through the first hole to the bottom surface of the cord plate. The first flowable sealant may flow from the bottom surface through the second hole to the second chamber. The first flowable sealant may flow from the second chamber through the vent hole in the cap. The cord plate may include a second conductor housing connected to the second chamber. The second conductor housing may include a second filling hole. The method may include injecting a second flowable sealant into the second filling hole. The second flowable sealant may flow from an inner surface of the second conductor housing into the third chamber. The second flowable sealant may flow from the third chamber through the third hole to the bottom surface of the cord plate. The second flowable sealant may flow from the bottom surface through the second hole to the second chamber. The second flowable sealant may flow from the second chamber through the vent hole in the cap. Alternately, a flowable sealant may be injected into the inner cavity through the vent hole.

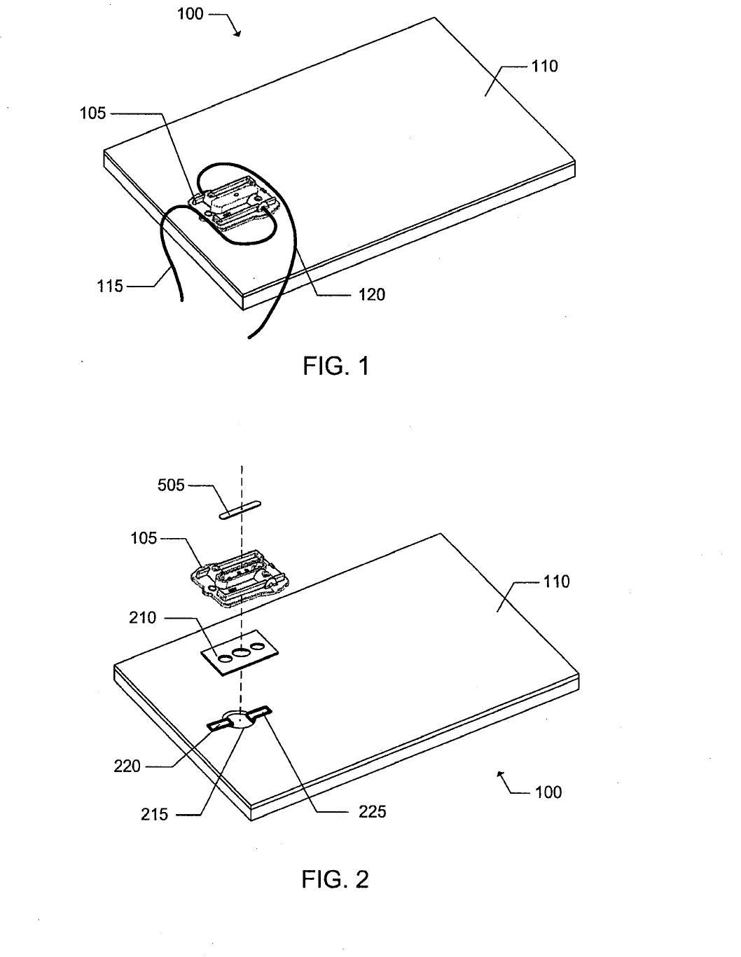

As shown in FIG. 1, a photovoltaic module 100 may include a cord plate 105. The cord plate 105 may serve as a junction box. The cord plate 105 may receive one or more electrical wires (e.g. 115, 120) and connect the module 100 to other electrical devices or modules. In particular, a first electrical wire 120 and a second electrical wire 115 may be connected to the module 100 through the cord plate 105. The cord plate 105 may be constructed from polycarbonate, plastic, resin, rubber, or any other suitable material. During installation, the cord plate 105 may be affixed to a cover plate 110 of the module 100, and an adhesive layer 210 may be inserted between the cord plate 105 and cover plate 110. Once electrical connections have been made, a flowable sealant may be injected into voids within the cord plate 105 to restrict moisture from accessing the electrical connections and internal surfaces of the module 100.

As shown in FIG. 2, an adhesive layer 210 may be inserted between the cord plate 105 and a cover plate 110 during installation. The adhesive layer 205 may be any suitable adhesive such as acrylic foam tape. In particular, 3M VHB Acrylic Foam Tape (product number 5952) or 3M FAST Acrylic Foam Tape may be used. Alternately, the adhesive layer 210 may be a liquid-based adhesive such as silicone, polyurethane, epoxy, or any other suitable liquid adhesive. Before the adhesive layer 210 is inserted between the cord plate 105 and cover plate 110, one or more contacting surfaces may be primed or otherwise treated to improve adhesion. For example, isopropyl alcohol may be applied to the surfaces to remove contamination. Next, a bottom surface 430 of the cord plate 105 may be flame treated to improve adhesion. Alternately, a liquid primer may be employed to prepare the mating surfaces for joining.

The cover plate 110 serves as a protective cover for the rear side of the module 100. The cover plate 110 may include a transparent protective material such as borosilicate glass, soda lime glass, or polycarbonate. Alternately, the cover plate 110 may be a non-transparent material such as Coveme's APYE or 3M's polymer back sheet. As shown in FIG. 2, the cover plate 110 may contain a hole 215 which allows a first lead 220 and a second lead 225 to reach an outer surface of the module 100. The first lead 220 may be a positive lead and the second lead 225 may be a negative lead. During assembly of the module 100, the first lead 220 may be attached to the first electrical wire 120. Similarly, the, second lead 225 may be attached to the second electrical wire 115. These electrical connections may be secured by soldering, brazing, spot welding, wire nuts, or any other suitable joining technique.

The cord plate 105 may include a top surface 365 and a bottom surface 430. As shown in FIG. 4, the bottom surface 430 of the cord plate 105 may be substantially flat to improve mating with the adhesive layer 210 and cover plate 105. The bottom surface 430 may include a first and a second access hole (420, 425). A first access hole 420 may permit access to the first lead 220 on the module 100, thereby exposing the first lead 220 and permitting the first conductor 120 to be joined to the first lead 220. Similarly, a second access 425 hole may expose a second lead 225 on the module 100, thereby permitting it to be joined to the second conductor 115.

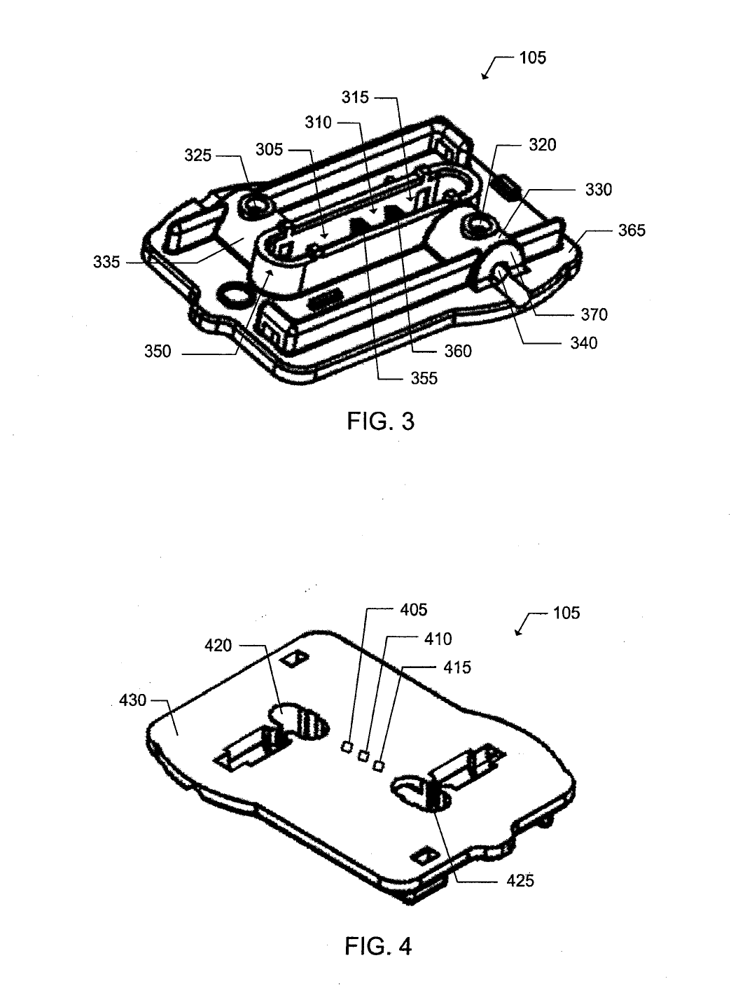

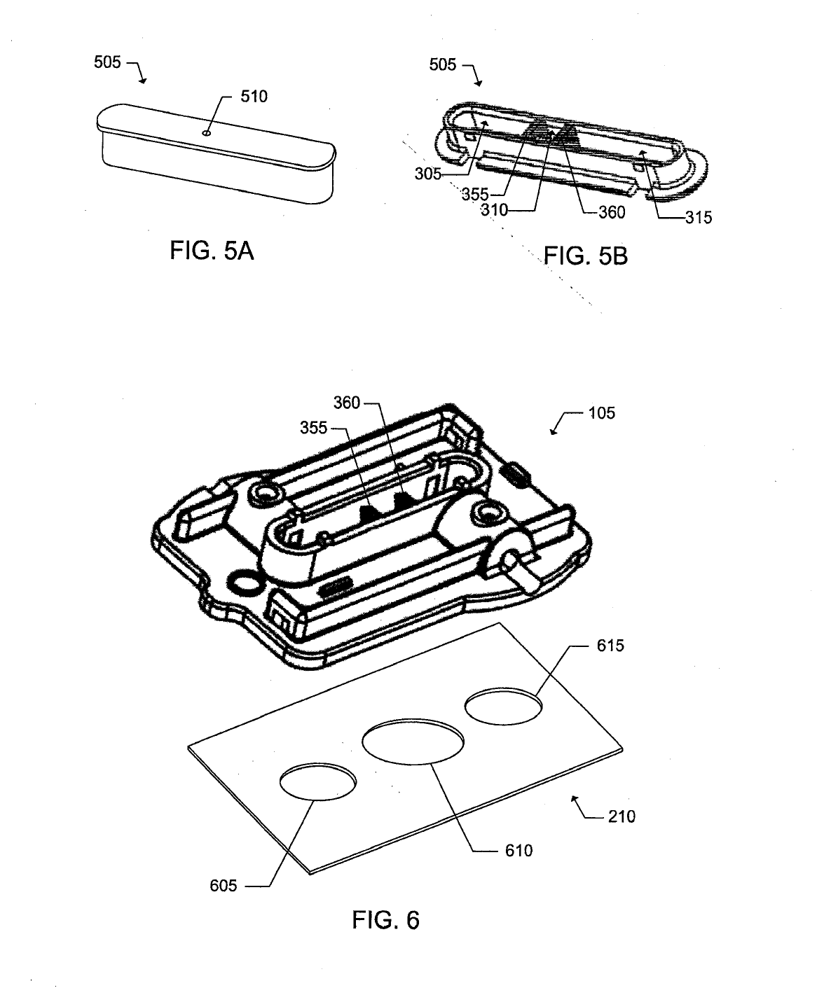

As shown in FIG. 3, the top surface 365 of the cord plate 105 may include an inner cavity 350 positioned near the center of the cord plate 105. The inner cavity 350 may include two partitions (355, 360) that effectively divide the inner cavity 350 into three chambers (305, 310, 315). For example, a first partition 355 may separate a first chamber 305 from a second chamber 310, and a second partition 360 may separate a second chamber 310 from a third chamber 315. The first and second partitions (355, 360) may be located within the inner cavity 350 as shown in FIGS. 3 and 6, or the partitions (355, 360) may be located within the cap as shown in FIG. 5B. Although the inner cavity 350 is depicted as a long slender cavity, this is not limiting. For example, the inner cavity 350 may be square, round, or any other suitable shape.

The inner cavity 350 may accommodate a plurality of bypass diodes connected in parallel to solar cells. If reverse biasing of a cell occurs due to a mismatch in short-circuit current between series connected cells, the bypass diode may provide an alternate current path around the reverse biased cell. As a result, the bypass diode protects cells from being damaged when the module 100 is partially shaded, has a broken cell, or experiences a cell string failure.

The cord plate 105 may include a plurality of holes extending from the inner cavity 350 to a bottom surface 430. For example, the cord plate 105 may have a first passage 405 extending from the first chamber 305 to the bottom surface 430. Similarly, the cord plate 105 may have a second passage 410 extending from the second chamber 310 to the bottom surface 430 and a third passage 415 extending from the third chamber 315 to the bottom surface 430. The first, second, and third passages may have any suitable shape or size that permits flowable sealant to pass through. To improve flow of sealant through the passages (405, 410, 415), and thereby decrease required injection pressure, the inlets and outlets of the passages may contain radial chamfers.

As shown in FIG. 3, the cord plate 105 may include one or more conductor housings protruding from the top surface 365. The conductor housings (330, 335) may be configured to receive and secure conductors. For example, a first conductor housing 335 may receive a first conductor 120, and a second conductor housing 330 may receive a second conductor 115. Once a conductor (e.g. 115, 120) is inserted into a housing, the inner cavity may provide access to an end of the conductor and thereby enable formation of an electrical connection. For example, an end of the first conductor 120 may be joined to the first lead 220 of the module 100. As mentioned above, these electrical connections may be formed by soldering, brazing, spot welding, wire nuts, or any other suitable joining technique.

The conductor housings (330, 335) may be integral to the cord plate. Alternately, the housings may be separate components fastened to a surface of the cord plate 105. The conductors may fit snugly into an inner surface of each housing. Also, the housings may contain retention features that prevent the conductors from being withdrawn from the housing. For example, inward facing barbs may be included on the inner surface of the housing. The barbs may allow the wire to be easily inserted into the housing but, if an attempt is made to withdraw the wire, the barbs may penetrate the wire sheath and resist withdrawal.

As shown in FIG. 6, the adhesive layer 210 may contain a plurality of holes. A first hole 605 may permit access to the first lead 220 on the module 100, thereby allowing the first conductor 120 to be joined to the first lead 220. Similarly, a second hole 615 may expose a second lead 225 on the module 100. In previous modules, the adhesive layer 210 covered the hole 215 in the cover plate 110, thereby restricting flowable sealant from accessing the hole 215. But the hole 215 in the cover plate 110 provides access to the internal surfaces of the module 100, and it is desirable to protect those internal surfaces. Therefore, a third hole 610 has been added to the adhesive layer 210 which provides access to the hole 215 in the cover plate 110. As a result of the third hole 610 in the adhesive layer 210, flowable sealant now enters the hole 215 in the cover plate 110 and protects the exposed internal surfaces of the module 100.

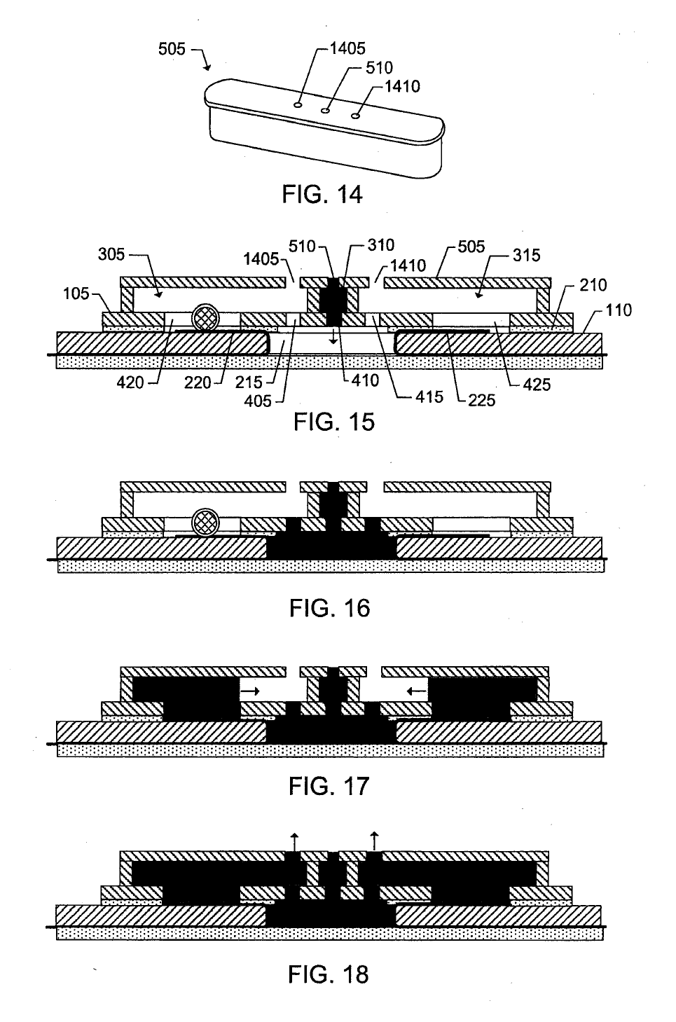

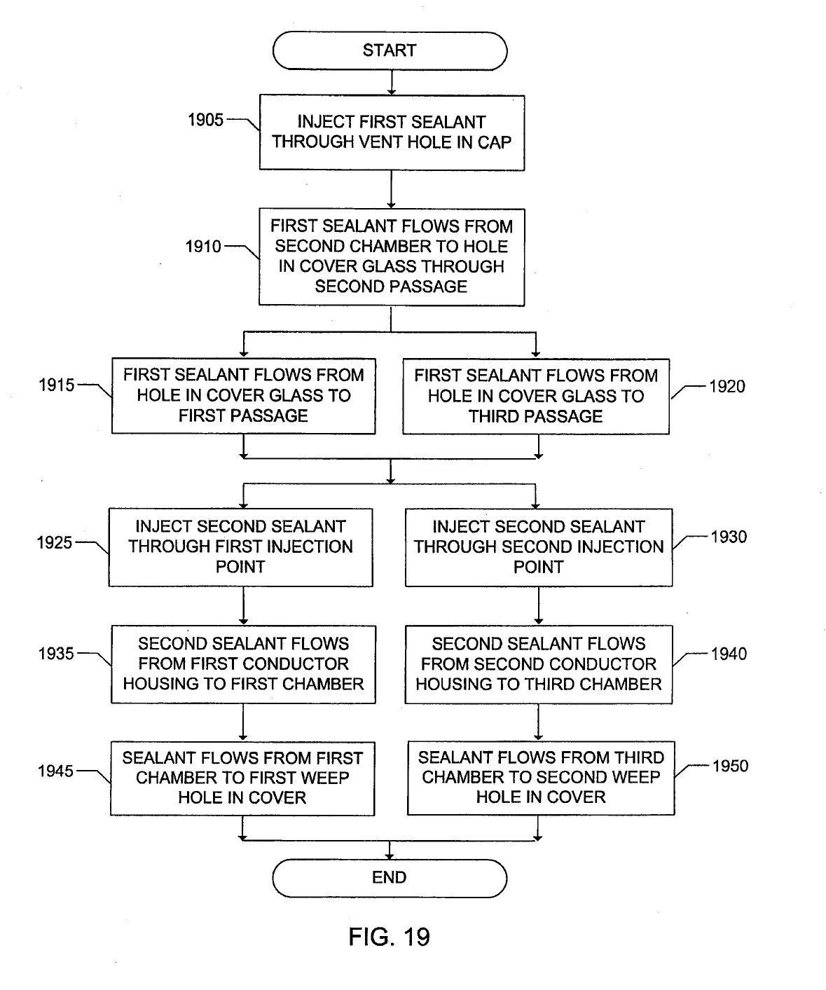

FIG. 5A shows a top perspective view of a cap 505 for the inner cavity 350, and FIG. 5B shows a bottom perspective view of the cap 505. The cap 505 may be removably attached to the inner cavity 350. The cap 505 may be attached to the inner cavity 350, thereby preventing moisture or debris from entering the inner cavity 350. The cap 505 may include one or more vent holes 510 which permit air and excess sealant to pass through. The cap 505 may also include one or more weep holes (e.g. 1405, 1410), as shown in FIG. 14, which permit air and excess sealant to pass through. A watertight seal may be formed between the cap 505 and the inner cavity 350. For example, the cap 505 or cavity 350 may include a rubber seal, o-ring, or any other suitable watertight seal.

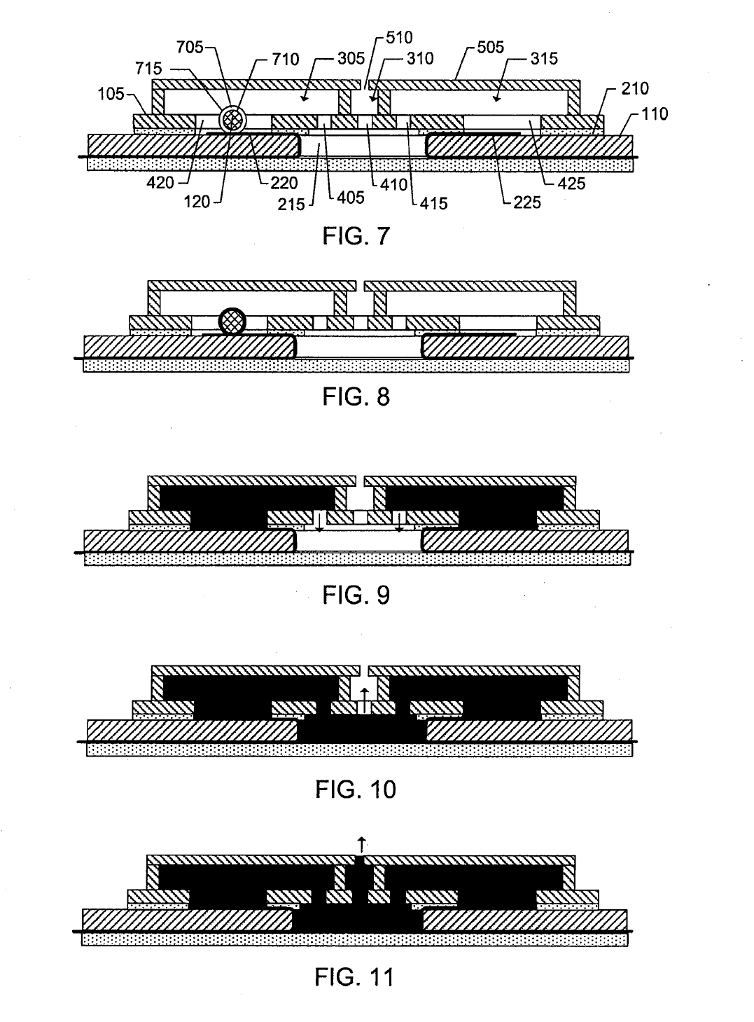

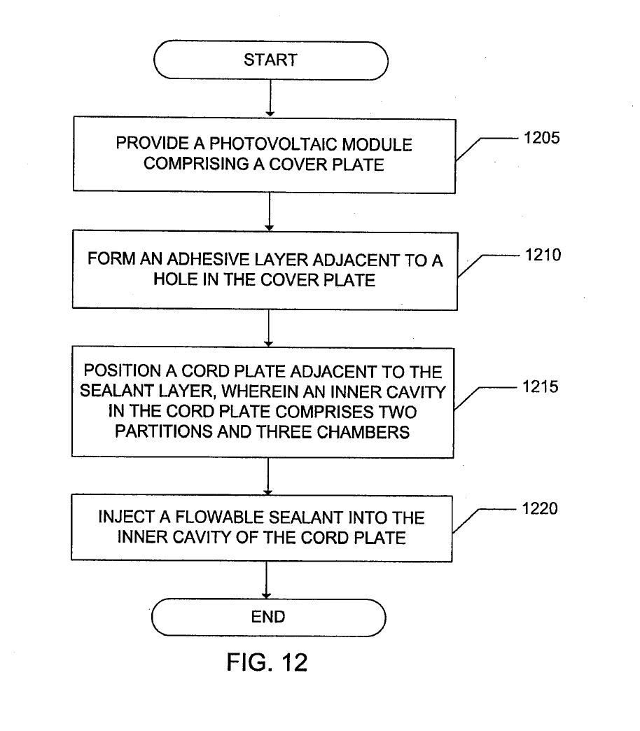

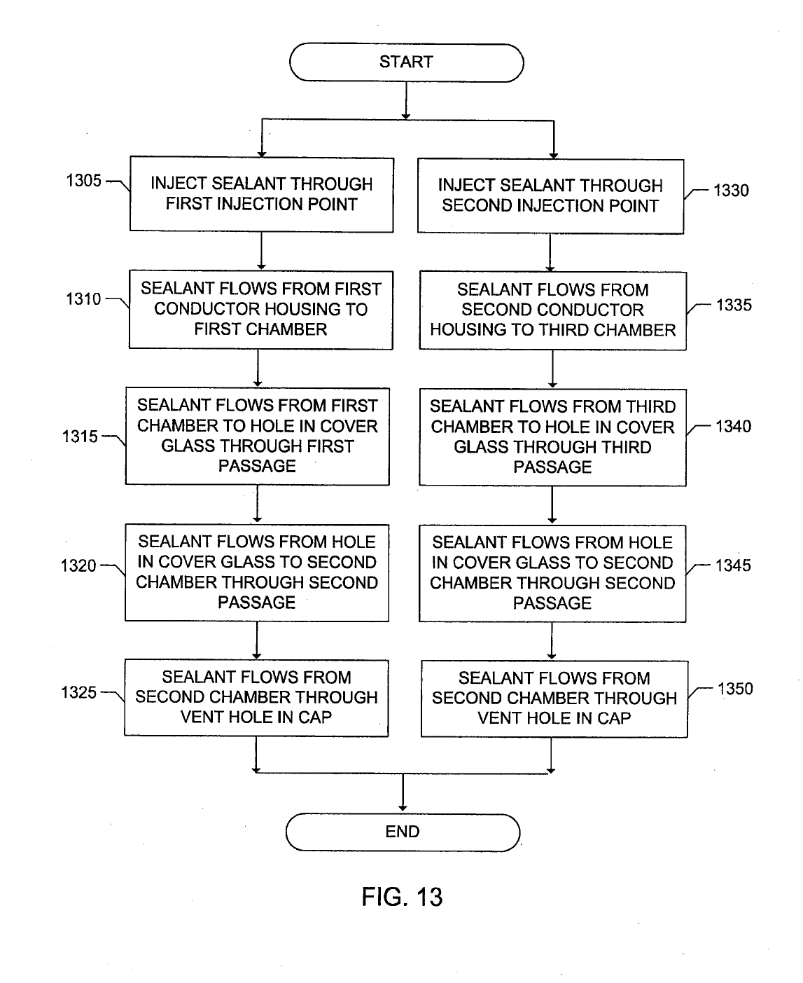

After the conductors (e.g. 115, 120) are adequately connected and secured, the cord plate 105 may be filled with a flowable sealant to keep moisture from penetrating internal surfaces of the photovoltaic module 100. FIGS. 7-11 show cross sectional views of cord plates affixed to modules. In particular, the figures depict sequential stages of a process of injecting flowable sealant into a cord plate 105. Two filling pathways are shown which extend from a pair of filling holes (320, 325) to a vent hole 510.

The flowable sealant may include a silicone rubber compound such as a room temperature vulcanizing (RTV) silicone. Alternately, the flowable sealant may include any suitable sealant such as, for example, acrylic, polysulfide, butyl polymer, epoxy, or polyurethane. The flowable sealant may be a one-component, two-component, or higher-component sealant. The sealant may be heated to reduce its viscosity thereby improving flow through narrow passages.

The cord plate 105 may have one or more sealant injection points. In FIG. 3, a first injection point 325 is shown atop the first conductor housing 335, and a second injection point 320 is shown atop the second conductor housing 330. This is not limiting. For example, the first injection point may be located adjacent to the first chamber 305. Alternately, the first injection point may be located at any position on the top surface 365 of the cord plate 105 so long as an access passage is provided to the first chamber 305. Similarly, the second injection point may be located adjacent to the third chamber 315 or at any position on the top surface 365 of the cord plate 105. FIG. 7 depicts a first stage in a filling process. Flowable sealant is injected into the first injection point 325 atop the first conductor housing 335. In the cross-sectional view, an annular clearance volume 705 is visible between an outer surface 710 of the first conductor 120 and the inner surface 715 of the first conductor housing 335. As shown in FIG. 8, the annular clearance volume 705 provides a pathway for flowable sealant to reach the first chamber 305 of the inner cavity 350.

Once the flowable sealant reaches the first chamber 305, it fills the chamber as shown in FIG. 9. Similarly, flowable sealant that is injected into the second injection point 320 enters and fills the third chamber 315. Once the first chamber 305 is full, the sealant passes through the first passage 405 and begins to fill the hole 215 in the cover plate 110 as shown in FIG. 10. Similarly, sealant passes from the third chamber 315 to the hole 215 in the in cover plate 110 through the third passage 415 where it covers the internal surfaces of the module 100. Once the hole 215 in the cover plate is filled with sealant, the sealant flows through the second passage 410 into the second chamber 310 as shown in FIG. 11. The vent hole 510 in the cap 505 allows displaced air to be evacuated from the inner cavity 350 as it fills with sealant. Excess sealant may also be forced out of the vent hole 510 and can be wiped off to produce a more aesthetically appealing installation.

The first and second conductor housings (330, 335) may each contain a barrier seal to prevent sealant from oozing out. For example, the second conductor housing 330 may contain a first barrier seal disposed between an inner surface 340 of the second conductor housing 330 and an outer surface of the second conductor 115. When the sealant is injected into the second injection point 320, it not only travels toward the inner cavity 350, but also travels toward an end 370 of the housing 330. If no barrier seal is present, the sealant will ooze from the second conductor housing 330. This may be undesirable, because the installer may need to remove the excess sealant and installation time increases. Thus, a barrier seal may be desirable.

Although FIGS. 7-11 depict the filling process occurring in a particular direction, this is not limiting. For example, the filling process may occur as shown in FIG. 15-18 using a cap 505 as shown in FIG. 14. The filling process may utilize two sealant materials. A first flowable sealant may be introduced through the vent hole 510 as shown in FIG. 15, wherein the vent hole 510 serves as a filling hole. The first flowable sealant may then fill the second chamber 310. Once the second chamber 310 is full, the sealant may pass through the second passage 410 and begin to fill the hole 215 in the cover plate 110 as shown in FIG. 16. A second flowable sealant may be injected into the first injection point 325 atop the first conductor housing 335 as shown in FIG. 17. The annular clearance volume 705 provides a pathway for second flowable sealant to reach the first chamber 305 of the inner cavity 350. Similarly, a second flowable sealant may be injected into the second injection point 320 atop the second conductor housing 330 where it then travels to the third chamber 315 of the inner cavity 350. The second flowable sealant may fill the first cavity and exit through a first weep hole 1405 as shown in FIGS. 14 and 18. Similarly, the second flowable sealant may fill the second cavity and exit through a second weep hole 1410 as shown in FIGS. 14 and 18. Excess sealant that is forced out of the weep holes (1405, 1410) can be wiped off to produce a more aesthetically appealing installation. Although FIGS. 15-18 show the second flowable sealant being injected in a particular direction, this is not limiting. For instance, the second flowable sealant may be injected through the first weep hole 1405 and may exit the first chamber 305 through the annular volume 705.

The properties of the first sealant material may be different than the properties of the second sealant material. In particular, properties such as adhesion, moisture permeability, viscosity, and dielectric strength may differ. This approach allows the first sealant material to be tailored for sealing the cover plate hole and allows the second sealant material to be tailored for sealing the wire ports.

Details of one or more embodiments are set forth in the accompanying drawings and description. Other features, objects, and advantages will be apparent from the description, drawings, and claims. Although a number of embodiments of the invention have been described, it will be understood that various modifications may be made without departing from the spirit and scope of the invention. In particular, steps depicted in figures may be executed in orders differing from the orders depicted. For example, steps may be performed concurrently or in alternate orders from those depicted. It should also be understood that the appended drawings are not necessarily to scale, presenting a somewhat simplified representation of various features and basic principles of the invention.

What is claimed as new and desired to be protected by Letters Patent of the United States is:

1. A cord plate for a photovoltaic module, the cord plate comprising:
a bottom surface; and
an inner cavity comprising:
a first partition separating a first chamber from a second chamber;
a second partition separating the second chamber from a third chamber;
a first passage extending from the first chamber to the bottom surface;
a second passage extending from the second chamber to the bottom surface; and
a third passage extending from the third chamber to the bottom surface.

2. The cord plate of claim 1, further comprising:
a first conductor housing connected to the first chamber; and
a second conductor housing connected to the second chamber.

3. The cord plate of claim 2, wherein the first conductor housing comprises a first filling hole.

4. The cord plate of claim 2, wherein the second conductor housing comprises a second filling hole.

5. The cord plate of claim 1, wherein the inner cavity further comprises a first access hole extending from the first chamber to the bottom surface, and wherein the inner cavity further comprises a second access hole extending from the third chamber to the bottom surface.

6. The cord plate of claim 1, further comprising a cap configured to attach atop the inner cavity, the cap comprising a vent hole.

7. A method for assembling a photovoltaic module, the method comprising:
providing a photovoltaic module comprising a cover plate;
positioning a bottom surface of a cord plate proximate to a hole in the cover plate, wherein the cord plate comprises an inner cavity comprising a plurality of chambers extending to the bottom surface; and
filling the plurality of chambers with a flowable sealant wherein the flowable sealant flows from the inner cavity to the hole in the cover plate.

8. The method of claim 7, further comprising applying an adhesive layer between the cover plate and the cord plate, wherein the adhesive layer comprises an opening aligned with the hole in the cover plate.

9. The method of claim 7, further comprising inserting a first conductor into the inner cavity through a first opening in the cord plate.

10. The method of claim 7, further comprising inserting a second conductor into the inner cavity through a second opening in the cord plate.

11. The method of claim 7, wherein the inner cavity further comprises a first filling hole.

12. The method of claim 11, wherein the inner cavity further comprises a second filling hole.

13. The method of claim 11, wherein the inner cavity further comprises a vent hole.

14. The method of claim 13, wherein the plurality of chambers are interconnected to form a filling pathway extending from the first filling hole to the vent hole.

15. The method of claim 7, wherein the inner cavity comprises:
a first partition separating a first chamber from a second chamber;
a second partition separating the second chamber from a third chamber;
a first passage extending from the first chamber to the bottom surface;
a second passage extending from the second chamber to the bottom surface; and
a third passage extending from the third chamber to the bottom surface.

16. The method of claim 15, wherein the inner cavity further comprises a cap comprising a vent hole extending from the second chamber to an external surface of the cap.

17. The method of claim 15, wherein the cord plate further comprises a first conductor housing connected to the first chamber, wherein the first conductor housing comprises a first filling hole.

18. The method of claim 17, further comprising injecting a first flowable sealant into the first filling hole.

19. The method of claim 18, wherein the first flowable sealant flows from an inner surface of the first conductor housing into the first chamber.

20. The method of claim 19, wherein the first flowable sealant flows from the first chamber through the first hole to the bottom surface of the cord plate.

21. The method of claim 20, wherein the first flowable sealant flows from the bottom surface through the second hole to the second chamber.

22. The method of claim 21, wherein the first flowable sealant flows from the second chamber through the vent hole in the cap.

23. The method of claim 15, wherein the cord plate further comprises a second conductor housing connected to the second chamber, wherein the second conductor housing comprises a second filling hole.

24. The method of claim 23, further comprising injecting a second flowable sealant into the second filling hole.

25. The method of claim 24, wherein the second flowable sealant flows from an inner surface of the second conductor housing into the third chamber.

26. The method of claim 25, wherein the second flowable sealant flows from the third chamber through the third hole to the bottom surface of the cord plate.

27. The method of claim 26, wherein the second flowable sealant flows from the bottom surface through the second hole to the second chamber.

28. The method of claim 27, wherein the second flowable sealant flows from the second chamber through the vent hole in the cap.

29. The method of claim 16, wherein a flowable sealant is injected into the inner cavity through the vent hole.

30. A photovoltaic module comprising a cord plate, wherein the cord plate comprises:
a bottom surface; and
an inner cavity comprising:
a first partition separating a first chamber from a second chamber;
a second partition separating the second chamber from a third chamber;
a first passage extending from the first chamber to the bottom surface;
a second passage extending from the second chamber to the bottom surface; and
a third passage extending from the third chamber to the bottom surface.

31. The photovoltaic module of claim 30, further comprising:
a first conductor housing connected to the first chamber; and
a second conductor housing connected to the second chamber.

32. The photovoltaic module of claim 31, wherein the first conductor housing comprises a first filling hole.

33. The photovoltaic module of claim 31, wherein the second conductor housing comprises a second filling hole.

34. The photovoltaic module of claim 30, wherein the inner cavity further comprises a first access hole extending from the first chamber to the bottom surface, and wherein the inner cavity further comprises a second access hole extending from the third chamber to the bottom surface.

35. The photovoltaic module of claim 30, further comprising a cap configured to attach atop the inner cavity, the cap comprising a vent hole.

36. The photovoltaic module of claim 35, further comprising a first weep hole in the cap and a second weep hole in the cap.
